(19) United States
(12) Patent Application Publication
(10) Pub. No.: US 2023/0197870 A1
(43) Pub. Date: Jun. 22, 2023

(54) PHOTOVOLTAIC MODULE PROVIDED WITH A H2O GAS PERMEATION BARRIER LAYER

(71) Applicant: COMMISSARIAT A L'ENERGIE ATOMIQUE ET AUX ENERGIES ALTERNATIVES, Paris (FR)

(72) Inventors: Virginie BRIZE, Grenoble (FR); Stéphane CROS, Grenoble (FR)

(73) Assignee: COMMISSARIAT A L'ENERGIE ATOMIQUE ET AUX ENERGIES ALTERNATIVES, Paris (FR)

(21) Appl. No.: 18/086,178

(22) Filed: Dec. 21, 2022

(30) Foreign Application Priority Data
Dec. 21, 2021 (FR) 21/14093

(51) Int. Cl. H01L 31/048

(52) U.S. Cl. CPC H01L 31/0481

(57) ABSTRACT

A photovoltaic module including: several photovoltaic cells disposed side by side, and electrically connected to each other, an encapsulating assembly, configured to encapsulate the photovoltaic cells, and a barrier layer disposed at an interface between the encapsulating assembly and at least one photovoltaic cell, the barrier layer being configured to at least partially cover the at least one photovoltaic cell, and to have an O₂ gas transmission rate lower than that of the encapsulating assembly, and a water vapor transmission rate less than or equal to 10⁻² g/m²/day measured at 38° C. and 85% humidity level, so as to form a barrier to the transmission of water vapor and O₂ gas.

The present invention relates to the field of photovoltaic modules. The invention concerns in particular a specific architecture of a photovoltaic module comprising a layer forming barrier to the gaseous permeation and in particular H₂O gas. According to a second aspect, the invention relates to the manufacturing method of said photovoltaic module.

New-generation solar cells comprising a perovskite semiconductor material make it possible to obtain devices with high conversion efficiency. Photovoltaic panels made from thin-layer cells based on perovskite alone can be made at low temperature on a rigid substrate, such as glass, or on a flexible substrate, such as PET for example. This makes it possible to consider applications on a rigid support and on a flexible support. It is also possible to make tandem cells including two types of sub-cells, one from perovskite, the other from silicon or CIGS alloy (acronym for an alloy composed of copper, indium, gallium, and selenium) for example.

Nowadays, many efforts aim to improve yields and increase the life cycle of photovoltaic modules without losing efficiency. The modules are indeed subject to drastic conditions of temperature and humidity, they should withstand atmospheric gases, such as water, oxygen, and gaseous molecules resulting from the decomposition of constituent materials of the photovoltaic panel itself. It is known in particular that the encapsulant EVA (Ethylene-Vinyl Acetate) intended to encapsulate and protect cells, decomposes into acetic acid over time, under the effect of significant thermal cycling. However, this gaseous acid is corrosive for the constituents of the cells.

This problem of stability over time is further accentuated with the use of materials that are sensitive to the degradation mechanisms related to the presence of water and oxygen or another oxidizing molecule, such as a perovskite or organic semiconductor... which have increased sensitivity to atmospheric gases. This constraint involves defining encapsulation methods more rigorous than those used today, i.e. methods that considerably limit the oxidizing gases/molecules quantities reaching the solar device. These methods will also be beneficial to more traditional silicon-based technologies, for example by making it possible to further extend the life cycle of solar panels.

One of the objects of the present invention aims to overcome at least one of the aforementioned drawbacks. To this end, the invention suggests a photovoltaic module comprising:
several photovoltaic cells disposed side by side, and electrically connected to each other,
an encapsulating assembly configured to encapsulate the photovoltaic cells, and
a barrier layer disposed at an interface between the encapsulating assembly and at least one photovoltaic cell, the barrier layer being configured to at least partially cover the at least one photovoltaic cell, and to have an O₂ gas transmission rate lower than that of the encapsulating assembly, and a water vapor transmission rate less than or equal to 10⁻² g/m²/day measured at 38° C. and 85% humidity level, so as to form a barrier to the transmission of water vapor and O₂ gas.

The module of the invention configured in this manner comprises a barrier layer disposed between the encapsulating assembly and the photovoltaic cell so as to block the possibilities of entry of gases from the atmosphere through the encapsulating assembly. This offers an additional guarantee for the durability of the photovoltaic module, which is even more interesting when the concerned cells comprise a semiconductor material or any other constituent layer of the cell which is sensitive to gases, such as H₂O and O₂ gas, or to a gas resulting from the degradation of the encapsulating EVA or another material constituting the module.

By the terms “a barrier to transmission”, it is understood in this document a barrier which makes it possible to significantly reduce the permeation of said gases in the cell. Said gases diffuse in particular through the encapsulating assembly and are mainly stopped by the barrier layer.

This water vapor transmission rate of the barrier layer makes it possible to limit the permeation of H₂O gas. This rate is also well known to those skilled in the art by WVTR (acronym for Water Vapor Transmission Rate). This rate is, for example, measured according to one of the following standards: - ASTM E96, DIN 53122 or ISO 2528. It is also well known that even if this rate primarily reflects a water vapor barrier property, such a value may also constitute a guarantee against permeation to O₂ gas, acetic acid and ammonia.

According to one possibility, the photovoltaic module comprises a plurality of barrier layers, each being disposed between the encapsulating assembly and a respective photovoltaic cell. This arrangement is encountered in particular when the photovoltaic module comprises photovoltaic cells each having a separate substrate.

According to a concrete embodiment, the barrier layer comprises a material selected from silicon oxides, titanium oxides, alumina, or a multilayer stack of several of these materials.

According to one possibility, the barrier layer consists solely of a material selected from silicon oxides, titanium oxides, alumina, or a multilayer stack of several of these materials.

According to one arrangement, the barrier layer comprises a multilayer stack of alumina and silicon oxide.

According to another arrangement, the barrier layer comprises a multilayer stack of alumina and titanium oxide.

According to one variant, the barrier layer comprises a multilayer stack of alumina, titanium oxide and silicon oxide.

According to another variant, the barrier layer consists solely of alumina.

In particular, the barrier layer has a thickness comprised between 15 and 50 nm, in particular a thickness comprised between 20 and 40 nm and in particular a thickness of approximately 30 nm. The value of the WVTR rate decreases, i.e. the protection provided is maximum for an optimum in thickness which will depend on the details of the method or on the slight variation in the chemical composition (hydroxide rate in the layer for example). The more the layer is a barrier to water, the more it limits the risks of permeation for other gases as well. Furthermore, it is also necessary to find a good compromise between the thickness of the barrier layer and its optical and electrical properties, the manufacturing costs, the duration of its deposition, etc., for optimal use in a cell. For example, the thicker the alumina layer, the lower its light transmission.

According to one arrangement, the at least one photovoltaic cell comprises at least one sensitive layer, which is capable of degrading in the presence of humidity and/or O₂ gas, and the barrier layer at least partially covers said at least one sensitive layer.

In one embodiment, the sensitive layer is disposed within the photovoltaic cell. This is for example the case when the sensitive layer is an active layer. In this situation, the barrier layer covers the at least one sensitive layer without being in contact therewith.

Without contradiction to the fact that the barrier layer at least partially covers said at least one sensitive layer, the present invention provides for the fact that the barrier layer at least partially covers the side edges of the at least one photovoltaic cell and at least one face among a front face and a rear face of the at least one photovoltaic cell. In this case, the barrier layer is then advantageously disposed on the face of the cell which is most likely to be crossed by H₂O gas. It may be a face devoid of a barrier element, that is to say devoid of a layer or a substrate having for example a WVTR rate at least less than 10⁻² g/m²/day, such as a silicon substrate or a glass plate as will be seen in more detail later.

Conventionally, it is understood in the present document that the “front face” of a photovoltaic cell or a photovoltaic module is the face intended to receive a light flow. Conversely, the rear face is a face located on the opposite side to the front face.

According to one possibility, the photovoltaic cells are tandem cells each having a separate substrate. Each tandem cell includes an upper sub-cell comprising at least one sensitive layer, and the barrier layer at least partially covers the side edges and at least one front face of at least one of the photovoltaic cells. It should be understood herein that the “upper sub-cell” is the cell that is intended to receive a light flow first, as compared to a lower sub-cell. In this configuration, the lower sub-cell is based on silicon or based on a layer of CIGS deposited on a metallic substrate, and forms an effective barrier to permeation from the lower face. The upper sub-cell comprising the sensitive layer is underlying the front face of the photovoltaic cell so that the barrier layer is advantageously deposited on the front face.

In a particular case, the barrier layer at least partially covers the side edges and at least one front face of each of the photovoltaic cells.

According to another arrangement, the photovoltaic cells each have a separate substrate, and are electrically connected to each other by electrical contacts comprising at least one electrical connection tape deposited on the barrier layer of each of the photovoltaic cells so as to form an electrical interconnection network, the electrical interconnection network being connected respectively to the cathode and to the anode of the photovoltaic module by a first output electrical connection and a second output electrical connection deposited on the barrier layer.

The connection of the electrical interconnection network to the cathode and to the anode is also known by those skilled in the art under the expression “contact recovery”.

According to one possibility, each of the electrical contacts is an electrical connection tape deposited on the barrier layer of each photovoltaic cell.

Concretely, the electrical connection tape is a pressure-sensitive electrically conductive adhesive, such as the charge-collection tape 3007 supplied by the company 3M® (also known under the name 3M™ Charge-Collection Solar Tape 3700).

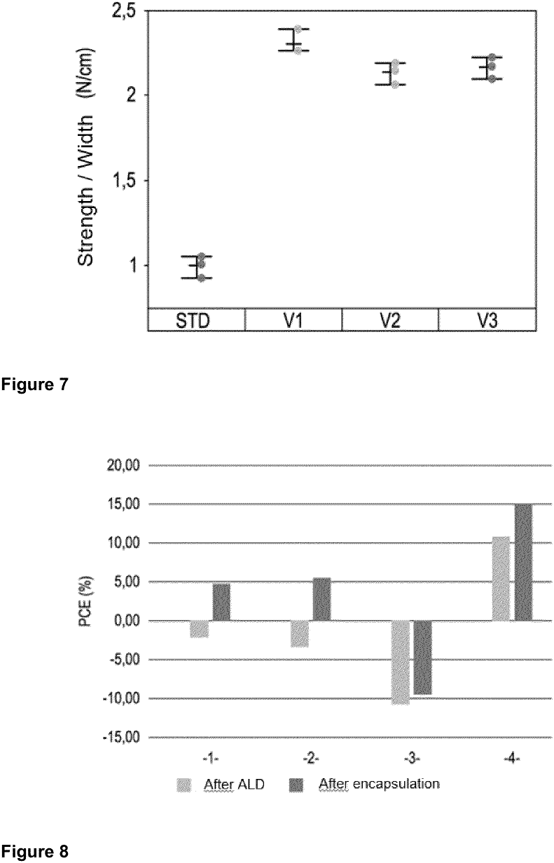

As will be shown in detail in the descriptive section of the present document, this arrangement of the electrical contacts on the barrier layer surprisingly allows an electrical contact to be effectively made and leads to a cell which gives the highest performance compared to other tested cells and in which the contacts are made prior to the barrier layer (refer to FIG. 7). This configuration is even more advantageous in that it facilitates making the electrical contacts. The steps of shielding contact areas on each of the cells prior to the formation of the barrier layer are not necessary. This also avoids the generation of leakage current.

According to one embodiment, the photovoltaic cells comprise perovskite-based thin-layer cells, formed on a common substrate (also called common “support” by those skilled in the art), and the barrier layer at least partially covers side edges and at least one rear face of the at least one of the photovoltaic cells. In this configuration, the rear face remains, indeed, the most likely to be permeable to H₂O gas. When the active layer of thin-layer cells is made from perovskite, these are formed by deposition on a common support, such as a glass plate, that is highly barrier to H₂O permeation (WVTR less than 10⁻² g/m²/day). Then, in view of its use of the cell, the structure will be turned over and the support will be placed on the front face of the module. The barrier layer of the invention is then advantageously disposed on the rear face, devoid of any protective element.

In this arrangement in which the photovoltaic cells are formed on a common substrate, the photovoltaic cells are electrically connected to each other by an internal interconnection network, the recovery of contacts between the internal interconnection network, the cathode and the anode of the photovoltaic module is made respectively by a first output electrical connection, and a second output electrical connection deposited on the barrier layer.

This configuration is also advantageous in that the electrical contact is obtained through the barrier layer.

According to one arrangement, the photovoltaic module further comprises a first protective layer and a second opposite protective layer, the first protective layer and the second protective layer being laminated on either side of the encapsulating assembly, in which are encapsulated the photovoltaic cells, the electrical contacts and the barrier layer.

In this document, the expression “protective layer” also means “protective cover” according to a terminology well known to those skilled in the art.

According to one possibility, the first protective layer and the second protective layer are respectively disposed on the front face and the rear face of at least one cell of the plurality of photovoltaic cells.

According to one possibility, the encapsulating assembly is made from at least one polymer material selected from ethylene-vinyl acetate (or EVA), ionomers, in particular Surlyn®, PV5400 and PV8600 available from Dupont™ and combinations of these compounds.

According to one possibility, the encapsulating assembly is formed of at least one encapsulation layer from said at least one polymer material, configured to encapsulate the photovoltaic cells.

According to another arrangement, the encapsulating assembly is formed by at least one first encapsulation film disposed on at least one of the front face and the rear face of the photovoltaic cells and at least one second encapsulation film disposed on an opposite face of the photovoltaic cells, the at least first and second encapsulation films being made of at least one polymer material, intended to melt in a subsequent lamination step, allowing the encapsulation of the photovoltaic cells and also for adhering the first protective layer and the second protective layer and leading to a multilayer structure forming the photovoltaic module.

By the expression “on” in this document it should understood “in direct contact” or “in indirect contact”.

The first encapsulation film and the second encapsulation film are either made with the same polymer material or with different polymer materials.

According to one possibility, the first encapsulation film and/or the second encapsulation film each comprise a multilayer composition.

When the encapsulating assembly consists of EVA, the latter degrades into acetic acid over time and the barrier layer advantageously forms a barrier to the passage of acetic acid towards the at least one photovoltaic cell.

According to one possibility, the photovoltaic module comprises at least one gasket disposed against a peripheral side edge of the encapsulating assembly. This gasket limits any lateral permeation in the photovoltaic module, for gases that the encapsulating assembly and the barrier layer would not completely stop, in particular when the encapsulating assembly is made of EVA. The seal is of course disposed between the first protective layer and the second protective layer.

Concretely, the seal is PolyIsoButylene, also known by the acronym PIB, such as the B-dry product available from SAES Getters Group.

According to one second aspect, the invention suggests a method for manufacturing a photovoltaic module as described above, in which the barrier layer is produced by an atomic layer deposition method. This atomic layer deposition method is well known to those skilled in the art under the expression ALD (acronym for Atomic Layer Deposition). This method makes it possible to deposit layers at the atomic scale, which guarantees high precision of deposition. A standard alumina deposition formula, for example, comprises a repetition of several hundred of cycles including a H₂O pulse, a purge of H₂O with N₂, a TMA (acronym for TriMethylAluminium) pulse and a purge of TMA with N₂.

Concretely, the atomic layer deposition method by ALD according to the invention ends with a cycle consisting of an H₂O oxidizing pulse so as to obtain hydroxyl bonds at the surface of the barrier layer, followed by a purge with an inert gas, such as N₂ or Ar, so as to remove the reaction by-products, in particular when the barrier layer is made of alumina or has a face exposed to the deposition of the alumina encapsulant. This last cycle of ALD facilitates the subsequent adhesion with the at least one encapsulation layer, formed for example of ionomer or EVA during the production of the encapsulating assembly (refer to FIG. 2).

According to one possibility, the atomic layer deposition is carried out at a temperature below 130° C., and preferably at a temperature of approximately 100° C. These temperatures are in a low average compared to standard temperatures. They limit the risks of degradation of the layers of the photovoltaic cells.

Concretely, the method comprises a step i) of electrically connecting the photovoltaic cells to each other by depositing an electrical connection tape on the barrier layer of each of the photovoltaic cells, in particular when the photovoltaic cells each have a separate substrate, and /or a step ii) of recovery of contacts carried out by forming a first output electrical connection and a second output electrical connection on the barrier layer.

This arrangement allows contacts through the barrier layer and to obtain improved performance compared to the method in which the arrangement of the contact tapes and/or the electrical connections are deposited before the step of depositing the barrier layer.

It should be noted that the output electrical connections are necessary for the photovoltaic modules of cells each having a separate substrate as for the photovoltaic modules of cells formed on a common substrate, for a recovery of contact between the network connecting the cells to the cathode and to the anode of the photovoltaic module.

According to one arrangement, the method further comprises:
a step j) of forming a multilayer structure formed successively by:
   the first protective layer,
   at least one first encapsulation film,
   the photovoltaic cells electrically connected to each other,
   at least one second encapsulation film, and
   a second protective layer, and
a step k) of laminating the multilayer structure obtained in step j) so as to form the encapsulating assembly from the first encapsulation film and the second encapsulation film, the encapsulating assembly configured to encapsulate the photovoltaic cells, being disposed between the first and second protective layers.

Step k) of laminating the photovoltaic module comprises the application of a temperature less than or equal to 130° C.

Concretely, step k) of lamination is carried out with a pressure of approximately 100 kPa (1000 mbar).

According to other features, the photovoltaic module according to the invention includes one or several of the following optional features considered alone or in combination:
the first protective layer disposed on the front face consists of a transparent substrate, such as a transparent glass plate, a transparent stack of polymers, comprising for example a polymer from the acrylate family, such as polymethyl methacrylate (PMMA) or a 510-F composition available from 3M® comprising a transparent fluoropolymer film and a PET film assembled by a pressure-sensitive adhesive layer.
the second protective layer placed on the rear face consists of a transparent substrate, such as a transparent glass plate, or a multilayer containing PET between two layers of fluorinated polymers such as PVF or PVDF.
The first protective layer or the second protective layer comprises the common substrate on which the photovoltaic cells are formed.

Other aspects, objects and advantages of the present invention will appear better on reading the following description of two embodiments thereof, given by way of non-limiting example and made with reference to the appended drawings. In the remainder of the description, for the sake of simplification, identical, similar or equivalent elements of the different embodiments bear the same reference numerals. The figures do not necessarily respect the scale of all the elements represented so as to improve their readability and in which:

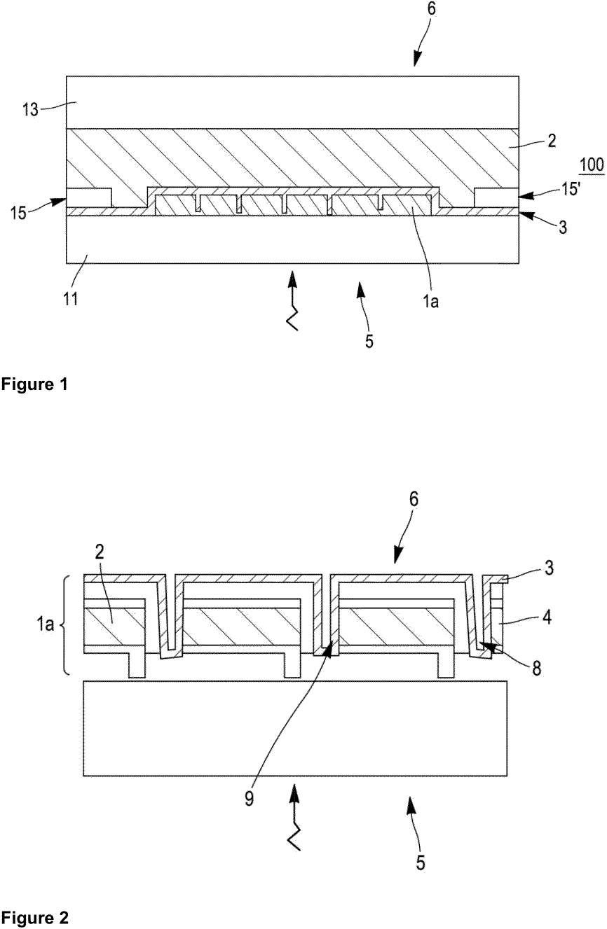

FIG. 1 represents a schematic sectional view of a portion of a photovoltaic module of thin-layer cells according to a first embodiment of the invention.

FIG. 2 represents an enlarged schematic view of a thin-layer cell according to the embodiment of FIG. 1.

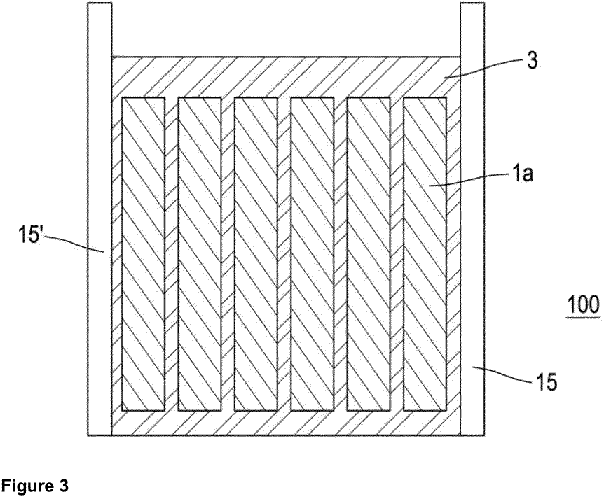

FIG. 3 represents a schematic view from above of a portion of a photovoltaic module of thin-layer cells according to the embodiment of FIG. 1.

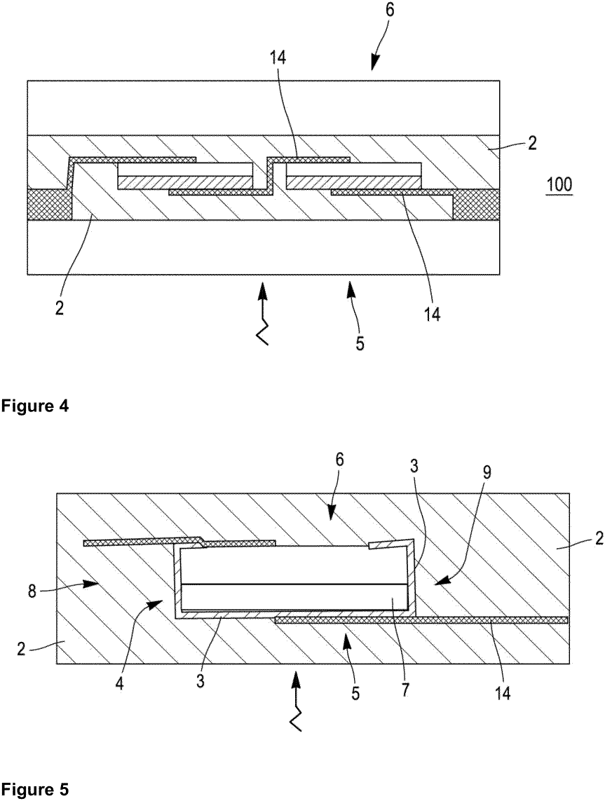

FIG. 4 represents a schematic sectional view of a portion of a photovoltaic module of tandem cells according to a second embodiment of the present invention.

FIG. 5 represents an enlarged schematic view of a tandem cell according to the embodiment of FIG. 4.

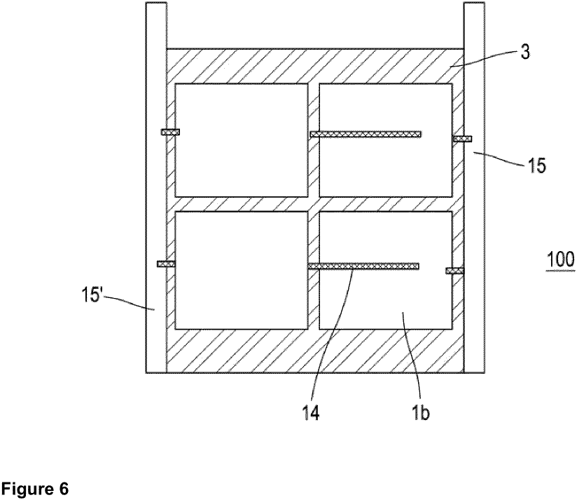

FIG. 6 represents a schematic view from above of a portion of a photovoltaic module of tandem cells according to the embodiment of FIG. 4.

FIG. 7 represents the results of experimental measurements of the adhesion strength of an encapsulating assembly on an alumina barrier layer according to different barrier layer deposition recipes.

FIG. 8 represents the results of experimental measurements of efficiency of different cells comprising electrical contacts deposited before or after the deposition of the alumina barrier layer.

As illustrated in the figures, the invention relates to a photovoltaic module 100 comprising photovoltaic cells 1a, formed and on a common substrate 11 (FIGS. 1 to 3) or photovoltaic cells 1b each having a separate substrate and disposed side by side (FIGS. 4 to 6), the module 100 comprising a barrier layer 3 covering at least in part the side edges and one face of the photovoltaic cells 1a,b, itself being encapsulated by an encapsulating assembly 2.

In a first embodiment illustrated in FIGS. 1 to 3, the photovoltaic module 100 is formed of several thin-layer photovoltaic cells 1a, formed on a common substrate, an encapsulating assembly 2, and an alumina barrier layer 3 disposed at the interface between the encapsulating assembly 2 and the photovoltaic cells 1a. More precisely, the barrier layer 3 covers the photovoltaic cells 1a so as to form a barrier to the transmission of water vapour, O₂ gas, or even ammonia or acetic acid (FIG. 2). The barrier layer 3 is made of alumina and has indeed transmission rates for water vapor and O₂ gas lower than those of the encapsulating assembly 2. The barrier layer 3 is deposited by ALD over a thickness of approximately 30 nm so as to present a WVTR rate less than or equal to 10⁻² g/m²/day measured at 38° C. under a humidity rate of 85%. According to different efficiency needs of the barrier layer, the thickness of the layer varies between 15 and 50 nm.

This barrier layer 3 deposited by ALD is dense, it has few defects so that a fine thickness is sufficient to form a barrier to the transmission of the majority of gases. The production of electrical contacts remains possible through this fine thickness, as developed hereinbelow.

According to possible embodiments, the barrier layer 3 is made of alumina, silicon oxide, titanium oxide, or formed from a multilayer stack of several of these materials.

In this first embodiment, the cells 1a comprise a sensitive layer 4, that is to say a layer 4 which is capable of degrading more or less rapidly in the presence of water vapor and/or O₂ gas, for example a sensitive layer 4 from perovskite or organic material. In this case, the barrier layer 3 covers said sensitive layer 4, without however being in direct contact with the latter. The enlargement of FIG. 2 illustrates in detail the covering of the sensitive layer 4 when it is an active layer located within a stack of layers forming the photovoltaic cell. It is possible to observe in particular that the barrier layer 3 covers at least partially the side edges 8, 9 of each of the cells and at least the rear face 6 of the cell 1a. Indeed, the protection of the front face 5 of the cell is already ensured at the time of its formation: the thin-layer cell 1a comprising the perovskite layer is formed from a support 11 intended to form the front face 5 of the cell (FIG. 2). This support 11 meets transparency criteria and it is also selected to ensure the function of the first protective layer 11, in particular against the permeation of H₂O and O₂ gases. The support is then selected so as to have a WVTR rate of less than 10⁻² g/m²/day. It may consist of a glass plate, or of a highly gas-barrier flexible film such as the 510-F film from 3M®.

Insofar as the rear face 6 of the cell 1a is protected by the alumina barrier layer 3, the second protective layer 13 disposed on the rear face 6 of the module may be chosen to have a higher WVTR rate, for example lower than or equal to 1 g/m²/day (FIG. 1).

According to a particularity of this embodiment, the cells 1a are electrically connected to each other by an internal interconnection network, the recovery of contacts between the internal interconnection network and the cathode, and mutually between the internal interconnection network and the anode of the photovoltaic module 100 is produced respectively by a first output electrical connection 15 and a second output electrical connection 15′deposited on the barrier layer 3 (step ii). FIG. 3 notably illustrates the output electrical connections 15 deposited on the barrier layer 3. These are electrically conductive adhesive tapes, sensitive to pressure and configured to connect the internal interconnection network between the cells 1a to the cathode and to the anode.

A first encapsulation film and a second encapsulation film from ionomer or a combination of EVA and from ionomer are each deposited on one face of the photovoltaic cells so as to form the encapsulating assembly 2 during a subsequent step k) of lamination.

The first protective layer 11 and the second protective layer 13 are then disposed on either side of the photovoltaic cells 1a and their electrical contacts 15, 15′ and the lamination step is carried out at a temperature less than or equal to 130° C. and a pressure of approximately 100 kPa (1000 mbar step k), without affecting cell performance as can be shown later in FIG. 8.

FIGS. 4 to 6 illustrate a second embodiment of the invention which differs from the first mode and in that the cells are, in particular, tandem cells 1b each having a separate substrate. These cells 1b comprise an active and sensitive layer 4 from perovskite disposed within an upper sub-cell 7. The barrier layer 3 is disposed so as to cover at least one front face 5 and side edges 8, 9 of the cell 1b (FIG. 5). The lower sub-cell comprising a silicon substrate, or a layer of CGIS on a support, forms an effective barrier to the permeation of H₂O and O₂ gases on the rear face 6 (FIG. 4).

Also visible in FIG. 6, the cells 1b are electrically connected to each other by electrical contacts comprising at least one electrical connection tape 14 (electrically conductive adhesive tapes) deposited on the barrier layer 3 of each of the cells 1b, so as to form an electrical interconnection network (step i). The electrical interconnection network is then connected respectively to the cathode and to the anode of the photovoltaic module 100 by a first output electrical connection 15 and a second output electrical connection 15′ deposited on the alumina barrier layer 3 (step ii or “recovery of contacts”) prior to formation of the encapsulating assembly 2.

The remainder of the method takes place according to the same concept as that of the cells 1a, an encapsulating assembly 2 is deposited in the form of a first encapsulation film and a second encapsulation film on either side of the cells 1b, two protective layers 11, 13 are disposed on either side of the structure 100 (multilayer structure formed in step j) and a lamination step is carried out (step k).

According to an arrangement not illustrated, a PIB seal is disposed against a peripheral side edge of the encapsulating assembly 2 before the arrangement of the first and second protective layers 11, 13 so as to reinforce the protection of the cells 1a and 1b.

In the two embodiments illustrated in FIGS. 1 to 6, the problem of the adhesion of the encapsulant, for example of EVA or of an ionomer, with the alumina barrier layer 3, arises. FIG. 7 illustrates the effects of different deposition formulas by ALD of the barrier layer 3 on the adhesion with an encapsulating assembly 2 based on ionomer. The y-axis illustrates the average strength over the width in N/cm and the x-axis references four different formulas. With the standard STD formula comprising the repetition of cycles including: a H₂O pulse, a purge of H₂O with N₂, a TMA pulse and a purge of TMA with N₂, the adhesion strength is very low. With formula V1 comprising the following cycles: TMA pulse and a purge of TMA with N₂, a H₂O pulse, a purge of H₂O with N₂, the adhesion strength is the best. The formula V2 combining the repetition of the cycles of the standard formula and a last cycle with a H₂O pulse then a purge of H₂O with N₂ also gives very good results. The formula V3 using the cycles of the standard formula but comprising at the end of each cycle a H₂O pulse followed by a purge of H₂O with N₂ leads to similar results. As indicated hereinabove, the probable explanation for the increase in adhesion, despite a deposition temperature below 130° C., lies in the formation of hydroxyl bonds at the surface of the barrier layer 3 and a purge making it possible to remove the reaction by-products.

FIG. 8 illustrates the results of experimental yield measurements carried out after the deposition of the barrier layer 3 and after the formation of the encapsulating assembly 2 from different cells. The measurements carried out on the first two cells show improved yields after formation of the encapsulating assembly 2 even if these barely exceed 5% (the y-axis represents the relative PCE). The measurements carried out on the third cell approach 10%. Finally, the measurements carried out on the fourth cell exceed 15% after formation of the encapsulating assembly 2. The notable difference between the first two cells and the last two cells lies in the fact that in the latter case, the electrical contacts 14, 15, 15′ were made on the barrier layer 3 whereas in the first two cases they were made before forming the barrier layer 3.

Thus, the present invention suggests a photovoltaic module 100 comprising a barrier layer 3 forming a barrier to the permeation of H₂O gas which has barrier properties to water vapour, to O₂ gases, to acetic acid and to ammonia. The gas barrier layer 3 is in fact a dense inorganic layer (non-porous, with low defect densities) in particular obtained by an ALD deposition technology. The barrier layer 3 is thus barely exposed to gas solubility problems. The latter may reverse the transmission behavior according to the gases (water and oxygen for example) in the case of organic materials, such as organic polymers. The barrier layer 3 according to the invention thus makes it possible to significantly improve the lifetime of the cells of a module 100, whether these cells 1 have a sensitive layer 4 or not. This barrier layer 3 does not interfere with the making of the electrical contacts 14, 15, which facilitates the manufacturing method and avoids the risk of leakage current.

1. A photovoltaic module comprising:
several photovoltaic cells disposed side by side, and electrically connected to each other,
an encapsulating assembly, configured to encapsulate the photovoltaic cells, and
a barrier layer disposed at an interface between the encapsulating assembly and at least one photovoltaic cell, the barrier layer being configured to at least partially cover the at least one photovoltaic cell, and to have an O₂gas transmission rate lower than that of the encapsulating assembly, and a water vapor transmission rate less than or equal to 10⁻² g/m /day measured at 38° C. and 85% humidity level, so as to form a barrier to the transmission of water vapor and O₂gas, and wherein a surface of the barrier layer has hydroxyl bonds.

2. The photovoltaic module according to claim 1, wherein the barrier layer layer comprises a material selected from silicon oxides, titanium oxides, alumina, or a multilayer stack of several of these materials.

3. The photovoltaic module module according to claim 1, wherein the barrier layer layer has a thickness comprised between 15 and 50 nm.

4. The photovoltaic module according to claim 1, wherein the at least one photovoltaic cell comprises at least one sensitive layer layer which is capable of degrading in the presence of humidity and/or O₂gas, and wherein the barrier layer layer at least partially covers the at least one sensitive layer layer.

5. The photovoltaic module according to claim 1, wherein the photovoltaic cells each have a separate substrate and are electrically connected to each other by electrical contacts comprising at least one electrical connection tape deposited on the barrier layer of each of the photovoltaic cells cells so as to form an electrical interconnection network, the electrical interconnection network being connected respectively to the cathode and to the anode of the photovoltaic module module by a first output electrical connection and a second output electrical connection deposited on the barrier layer layer.

6. The photovoltaic module according to claim 1,wherein the photovoltaic cells (1a) are formed on a common substrate and are electrically connected to each other by an internal interconnection network, the recovery of contacts between the internal interconnection network, the cathode and the anode of the photovoltaic module module are produced respectively by a first output electrical connection and a second output electrical connection deposited on the barrier layer layer.

7. The photovoltaic module according to claim 1, which further comprises a first protective layer layer and a second opposite protective layer the first protective layer and the second protective layer layer being laminated on either side of the encapsulating assembly, wherein are encapsulated the photovoltaic cells, the electrical contacts and the barrier layer layer.

8. The photovoltaic module according to claim 1, which further comprises a gasket disposed against a peripheral side edge of the encapsulating assembly.

9. A method for manufacturing a photovoltaic module according to claim 1, wherein the barrier layer is produced by an atomic layer deposition method.

10. The method for manufacturing a photovoltaic module according to claim 9, wherein the atomic layer deposition method is completed by a cycle consisting of a H₂O oxidizing agent pulse so as to obtain hydroxyl bonds on the surface of the barrier layer, followed by a purge with an inert gas.

11. The method for manufacturing a photovoltaic module according to claim 9, which comprises a step i) of electrically connecting the photovoltaic cells to each other by depositing an electrical connection tape on the barrier layer of each of the photovoltaic cells and/or a step ii) of recovery of the contacts carried out by forming a first output electrical connection and a second output electrical connection on the barrier layer.

12. The method for manufacturing a photovoltaic module according to claim 9, which comprises:
a step j) of forming a multilayer structure formed successively by:
the first protective layer,
at least one first encapsulation film,
the photovoltaic cells electrically connected to each other,
at least one second encapsulation film, and
a second protective layer, and
a step k) of laminating the multilayer structure obtained in step j) so as to form the encapsulating assembly from the first encapsulation film and the second encapsulation film, the encapsulating assembly, configured to encapsulate the photovoltaic cells, being disposed between the first and second protective layers.
